(19) United States
(12) Patent Application Publication
(10) Pub. No.: US 2008/0085479 A1
(43) Pub. Date: Apr. 10, 2008

(54) PATTERN FORMING METHOD AND DEVICE PRODUCTION PROCESS USING THE METHOD

(75) Inventors: Takako Yamaguchi, Kawasaki-shi (JP); Toshiki Ito, Kawasaki-shi (JP); Natsuhiko Mizutani, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/866,002

(22) Filed: Oct. 2, 2007

(30) Foreign Application Priority Data
Oct. 10, 2006 (JP) 2006-276062

(51) Int. Cl. G03F 7/20

(52) U.S. Cl. 430/327

(57) ABSTRACT

A pattern forming method for forming a pattern comprising a plurality of fine particles disposed on a substrate includes a step of forming, on the substrate, a silane coupling agent-containing layer containing an amino group-containing silane coupling agent; a step of forming a negative resist layer or a dissolution inhibition positive resist layer on the silane coupling agent-containing layer; a step of selectively removing the resist layer to expose the silane coupling agent-containing layer; and a step of disposing the plurality of fine particles on the exposed silane coupling agent-containing layer.

### FIELD OF THE INVENTION AND RELATED ART

The present invention relates to a pattern forming method and a process for producing a device such as a single electronic device, patterned media, a chemical sensor, a quantum dot laser device, a photonic crystal, or optical device.

In recent years, in the fields of various electronic devices, such as a semiconductor device, requiring fine processing, demands for high density and high integration of the devices are more and more increased.

In a semiconductor production process, a step playing an important role in forming a minute circuit pattern is a photolithographic step.

A current photographic step is performed principally by reduced (size) projection exposure but a resolution thereof is restricted by diffraction limit of light and is about ⅓ of a light source wavelength.

For this reason, the wavelength can be shortened by using an excimer laser or the like as an exposure light source, so that fine processing on the order of about 100 nm can be performed.

Thus, lithography is advanced in level of the fine processing but with a shorter light source wavelength, is accompanied with many problems such as an increase in size of a device, development of a lens in an associated wavelength region, a device cost, a corresponding resist cost, etc.

Further, in recent years, the following devices requiring a high density hole array pattern or dot array pattern have been proposed.

A single electronic device has been disclosed in Japanese Laid-Open Patent Application (JP-A) 2001-168317, patterned media have been disclosed in JP-A 2005-190624, and a chemical sensor has been disclosed in JP-A 2003-268592. Further, a quantum dot laser device has been disclosed in JP-A Hei 10-012968 and a photonic crystal optical device has been disclosed in JP-A Hei 11-218627.

However, these devices require higher precision fine processing technique than the semiconductor device, so that it is difficult to produce these devices in volume by the conventional lithographic technique.

On the other hand, as a cost-reduced and simple fine processing technique in place of the conventional lithographic technique, a method of arranging fine particles in a self-organizing manner or the like has been reported.

CHEN H. L. et al., Electrochem Solid-state lett., 8, G54 (2005) has proposed the following technique. A resist is patterned by using energy line to create exposed/non-exposed portions of a chemically active group at a substrate surface, so that a fine pattern is formed by utilizing an interaction between the chemically active group and fine particles.

This technique is a combined technique of the lithography with the self-organization. More specifically, on a substrate, an amino group-containing silane coupling agent layer and a chemically amplified positive resist layer are successively formed. Then, the resist layer is subjected to ultraviolet irradiation or electron beam lithography in a pattern and subjected to development to form an amino group-exposed portion at the exposed portion. The amino group-exposed portion and a methyl group-exposed portion, in order words, which are portions where the amino group is protected by the resist layer, are formed in a pattern.

When the substrate is dipped in a gold fine particle colloid solution, citric acid-coated gold fine particles selectively adhere to the amino group as the exposed portion, so that a pattern of the gold fine particles is formed.

However, production of the above described device such as the single electronic device, the patterned media, the chemical sensor, the quantum dot laser device, or the photonic crystal optical device requires a high-definition fine processing technique exceeding that for the semiconductor device.

For this reason, it is difficult to produce the above described device in volume by the conventional photolithographic technique.

In the above described pattern forming method, lithography with respect to the chemically amplified resist is used.

The chemically amplified resist generates acid from a photoacid generating agent at a portion exposed to ultraviolet rays or electron beam and the acid is diffused by pot exposure bake (PEB) performed after the exposure.

The amino group of the amino group-containing silane coupling agent constituting a layer formed as an underlying layer of the resist layer is linked with the acid generated by the exposure and the acid diffused during the PEB, thus being neutralized.

For this reason, an amount of the amino group of the silane coupling agent exposed at the exposed portion is decreased to lower a contrast in degree of adherence of the gold fine particles between the exposed portion and the non-exposed portion, so that the degree of adherence of the gold fine particles is decreased.

Further, it is difficult to improve uniformity in adherence and there is a possibility of an occurrence of a non-adherence portion in a fine particle pattern.

### SUMMARY OF THE INVENTION

A principal object of the present invention is to provide a pattern forming method capable of improving uniformity in adherence and ensuring a pattern formation at a necessary position without generating acid at an adherence portion of fine particles.

Another object of the present invention is to provide a device production process capable of producing various devices by using the pattern forming method.

According to an aspect of the present invention, there is provided a pattern forming method for forming a pattern comprising a plurality of fine particles disposed on a substrate, the method comprising:

a step of forming, on the substrate, a silane coupling agent-containing layer containing an amino group-containing silane coupling agent;

a step of forming a negative resist layer on the silane coupling agent-containing layer;

a step of selectively removing the negative resist layer to expose the silane coupling agent-containing layer; and

a step of disposing the plurality of fine particles on the exposed silane coupling agent-containing layer.

According to another aspect of the present invention, there is provided a pattern forming method for forming a pattern comprising a plurality of fine particles selectively disposed on a substrate, the method comprising:

a step of forming, on the substrate, a silane coupling agent-containing layer containing an amino group-containing silane coupling agent;

a step of forming a dissolution inhibition positive resist layer on the silane coupling agent-containing layer;

a step of selectively removing the positive resist layer to expose the silane coupling agent-containing layer; and

a step of disposing the plurality of fine particles on the exposed silane coupling agent-containing layer.

According to a further aspect of the present invention, there is provided a process for producing a device, comprising: producing a device by using the pattern forming method described above.

According to the present invention, it is possible to realize a pattern forming method which improves uniformity in adherence and ensured pattern formation at a necessary position without generating acid at an adherence portion of fine particles.

Further, by using the above described pattern forming method, it is possible to produce devices such as the single electronic device patterned media, the chemical sensor, the quantum dot laser device, and the photonic crystal optical device.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1(a) to 1(g) are schematic views showing steps for illustrating a pattern forming method according to an embodiment of the present invention.

FIG. 2 includes schematic views each showing a relationship between a pattern shape and an arrangement state of fine particles in the pattern forming method of the present invention.

FIG. 3 includes schematic views for illustrating a dry etching process using, as a mask, the fine particles prepared by the pattern forming method of the present invention.

FIG. 4 includes schematic views for illustrating a lift-off process using, as a mask, the fine particles prepared by the pattern forming method of the present invention.

FIGS. 5(a) to 5(g) are schematic views for illustrating an embodiment of the pattern forming method according to the present invention.

### DETAILED DESCRIPTION OF THE PREFERRED EMBODIMENTS

An embodiment of the pattern forming method according to the present invention will be described.

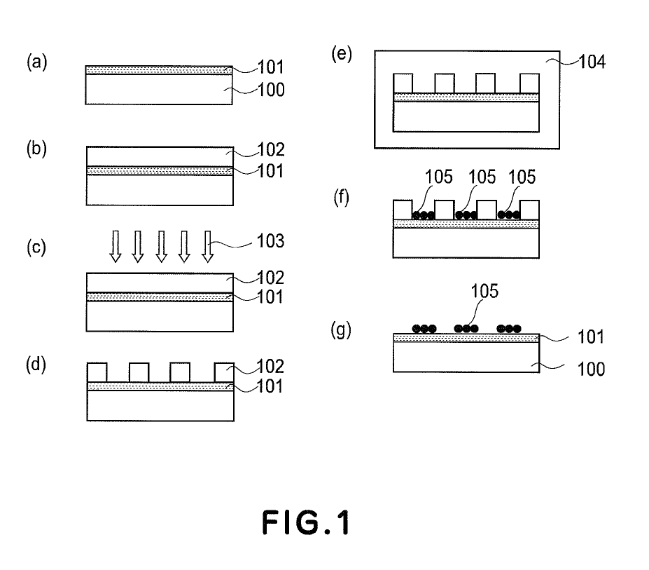

FIGS. 1(a) to 1(g) are schematic views for illustrating a pattern forming method in this embodiment.

Referring to these figures, reference numerals 100, 101, 102, 103, 104 and 105 represent a substrate, a silane coupling agent layer, a resist layer, radiation, a colloid solution, and fine particles, respectively.

In this embodiment, an amino group-containing silane coupling agent is fixed on the substrate 100 via a chemical bond (linkage).

As the substrate 100, it is possible to select an appropriate substrate from a wide range of substrate, depending on a desired device. For example, it is possible to use the wide range of substrates including a metal substrate; a semiconductor substrate; an insulating substrate such as a glass substrate or a quartz substrate; and these substrates coated with one or plural species of a resist, spin-on glass, metal, oxide, and nitride.

At the silane coupling agent-fixed surface, it is desirable that a hydroxyl group is formed.

In order to form the hydroxyl group at the surface of the substrate 100, it is desirable that the substrate 100 is subjected to pretreatment.

The pretreatment is performed by exposing the substrate surface to an acidic solution or an ultraviolet ray-ozone environment. As the acidic solution, it is possible to use sulfuric acid, hydrochloric acid, nitric acid, hydrogen peroxide, etc. These may be used singly or in combination of two or more species but a combination of sulfuric acid and hydrogen peroxide may preferably be employed. Particularly, the combination of sulfuric acid and hydrogen peroxide is suitable for the pretreatment of an Si substrate. As a means of the pretreatment with the acidic solution, for example, it is possible to employ application, spraying, dipping, etc.

Examples of the amino group-containing silane coupling agent may include (3-aminopropyl)-trimethoxysilane, and [3-(2-aminoethylamino)propyl]-trimethoxysilane.

On the substrate 100, the amino group-contain silane coupling agent is applied and heated to form the amino group-containing silane coupling agent layer 101.

The application of the silane coupling agent can be performed according to dipping, spin coating, spray coating, vapor deposition, or the like by using a liquid of the silane coupling agent alone or a solution of the silane coupling agent in an organic solvent. In the present invention, the dipping or the spin coating may preferably be used.

After the silane coupling agent is applied onto the substrate 100, it is preferable that the substrate 100 is heated as desired to complete a reaction of the silane coupling agent with the hydroxyl group on the substrate 100. The heating is performed at 80-200° C., preferably 80-150° C., by using a heating means such as a hot plate or a hot gas dryer.

By the above described treatment, a monomolecular layer 101 of the silane coupling agent from which the amino group is exposed is formed on the surface of the substrate 100 (FIG. 1(a)).

On the amino group-containing silane coupling agent layer 101, a resist which does not generate acid at a site from which the resist is to be removed by development is applied and heated to form the resist layer 102 (FIG. 1 (b)).

As the resist which does not generate acid at the site from which the resist is to be removed by development, it is possible to use a negative resist or a non-chemically amplified positive resist. As the non-chemically amplified positive resist, it is possible to use a dissolution inhibition resist but the resist is not limited thereto in this embodiment.

The application of the resist can be performed by dipping, spin coating, spray coating, vapor deposition, etc. After the application of the resist, by heating the resist as desired, an excessive resist solvent is vaporized. The heating is performed at a temperature lower than a glass transition temperature Tg of the resist by using a heating means such as a hot plate or a hot gas dryer. By the above treatment, the resist layer 102 is formed.

The thus formed resist layer 102 is ordinarily exposed to light in a pattern by using a known exposure device so as to be selectively removed later (FIG. 1(c)).

As the radiation 103 for exposure, it is possible to appropriately select and use visible ray, ultraviolet ray, far-ultraviolet ray, X-ray, electron beam, gamma-ray, molecular beam, ion beam, or the like but the following rays or beams may preferably be used.

It is preferable that mercury lamp light (wavelength: 436 nm, 405 nm, 365 nm, 254 nm), KrF excimer laser light (wavelength: 248 nm), ArF excimer laser light (wavelength: 193 nm), far-ultraviolet ray such as F₂ excimer laser light (wavelength: 157 nm) or extreme ultraviolet (EUV) ray (wavelength: 13 nm), or electron beam is used. These radiations may be used singly or in combination of two or more radiations.

As an exposure method during selective removal of the resist layer, near-field light generated from a photomask provided with a light blocking layer having an opening width narrower than a wavelength of light from an exposure light source may preferably be used.

The near-field light is not influenced by diffraction limit, so that it is possible to obtain a finer pattern.

As radiation for near-field light exposure, the above described radiations can be used. These radiations can also be used singly or in combination of plural radiations. The exposure to the near-field light is carried out by bringing the light blocking layer of the photomask into intimate contact with an object to be exposed.

A near-field light exposure device is inexpensive since a precision optical system and an expensive light source are not required, thus being particularly preferred in the present invention from the viewpoint of productivity.

In the above described exposure step, when a negative resist is used, a cross-linking reaction of a resist polymer occurs at the exposed portion.

In a subsequent development step, a non-exposed portion of the resist is dissolved in a developing liquid to expose the amino group-containing silane coupling agent.

Even in the case of the chemically amplified resist, when it is of the negative type, acid generated and diffused by the PEB is present only at the exposed portion, so that the acid does not adversely affect the amino group which constitutes the underlying layer of the non-exposed portion of the resist and is exposed after the development.

On the other hand, in the case where the non-chemically amplified positive resist is used as the resist in the above described exposure step, a reaction by which solubility of the resist is increased occurs at the exposed portion.

For example, in the case of the dissolution inhibition positive resist, a photoreactive substance functioning as a dissolution inhibitor of the resist polymer during the development causes a chemical reaction by being exposed to light to be lowered in its dissolution inhibition, thus increasing resist dissolution at the exposed portion.

The dissolution-increasing reaction does not generate acid, so that it does not adversely affect the amino group which constitutes the underlying layer of the exposed portion of the resist and is exposed after the development.

For this reason, on the substrate after the development (FIG. 1(d)), a portion at which the amino group-containing silane coupling agent layer 101 is covered with the resist layer and a portion at which the amino group-containing silane coupling agent layer 101 is exposed are formed corresponding to the pattern formed by the exposure.

Accordingly, the amino group exposure portion is not neutralized by the acid, so that reactivity at the fine particles adherence site can be ensured even after the resist patterning.

The substrate after the development is completed is dipped into the colloid solution 104 (FIG. 1(d)).

By this step, the fine particles 105 are selectively adhered to the exposed portion or non-exposed portion of the substrate to form a fine particle pattern (FIG. 1(f)).

Thereafter, the resist pattern is removed as desired (FIG. 1 (g)).

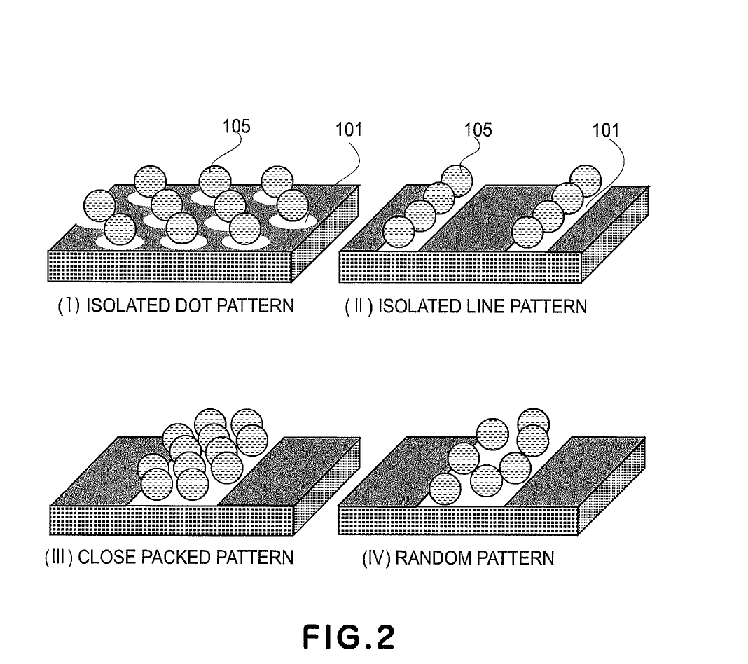

FIG. 2 includes schematic views each showing a relationship between a pattern shape and a fine particle arrangement state in the pattern forming method of this embodiment.

The pattern shape in this embodiment can be an isolated dot pattern in which one fine particle 105 is adhered at one minute dot-like exposed or non-exposed portion (FIG. 2(I)).

The pattern shape can also be an isolated line pattern in which fine particles 105 are arranged in a narrow line (FIG. 2(II)).

The pattern shape can also be a close packed pattern in which fine particles 105 are arranged at an exposed portion or non-exposed portion having a size larger than a size of the fine particles in a closest packing state (FIG. 2(III)).

The pattern shape can also be a random pattern in which fine particles 105 are randomly arranged at an exposed portion or non-exposed portion having a size larger than a size of the fine particles with a certain spacing created by a repulsive force between the fine particles.

Thus, the pattern shape can be appropriately changed depending on an objective device, so that the pattern shape in the present invention is not limited to the above described pattern shapes.

The fine particles may generally have an average particle size in a range of 0.5 nm or more to 500 nm or less and may preferably be selected from this range appropriately depending on a purpose.

The type of the fine particles is selected depending on an objective device but fine particles charged positively or negatively or fine particles having a terminal carboxylic group or a terminal carboxylic anhydride group may particularly preferably be used.

For example, gold fine particles or gold nanorods are negatively charged to create an electrostatic linkage with the amino group to be positively charged and present at the exposed portion.

Positively charged fine particles selectively adhere to the non-exposed portion of the substrate. The terminal carboxyl group of the fine particles and the amino group at the substrate surface are linked with each other by ionic bond. The terminal carboxylic anhydride group of the fine particles and the amino group at the substrate surface are easily reacted with each other at room temperature to form amide bond, thus being firmly linked with each other.

In the case where the single electronic device is produced, electroconductive fine particles such as fine particles of metal or metal oxide are used.

In the case of producing a magnetic recording medium having a magnetic bit array such as patterned media, it is possible to use magnetic metal fine particles such as those of Co, Ni, Fe, FePt, CoPt, CoNi, CoCr, CoP, CoNiP, FeCoB, FeCoNi, CoNiFeB, FeNi, FeCo, and CoNiPt.

In the case of producing the chemical sensor, metal fine particles are used. From the viewpoints of sensitivity and chemical stability, noble metal fine particles may preferably be used. Particularly, gold fine particles or gold nanorods may preferably be used.

In the case of producing the quantum dot laser device, e.g., semiconductor fine particles such as fine particles of Si, SiGe, GaAs, InGaAs, GaN, InP, InAs, AlGaAs, InGaAsP, GaInAlP, InGaN, and AlGaN may be used.

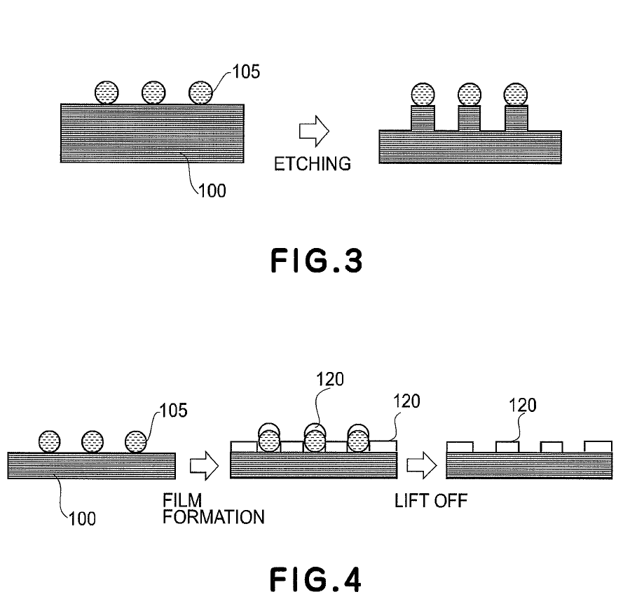

Further, a substrate material is processed by using the above formed pattern with the fine particles 105 as an etching mask, so that a dot array pattern may also be formed (FIG. 3). In FIG. 3, the silane coupling agent layer 101 formed on the substrate 100 is omitted.

In this case, the substrate material is selected depending on an objective device.

In the case where the single electronic device is produced, metal or metal oxide can be used as the substrate material.

In the case of producing a magnetic recording medium such as patterned media, it is possible to use, as the substrate material, magnetic metal such as Co, Ni, Fe, FePt, CoPt, CoNi, CoCr, CoP, CoNiP, FeCoB, FeCoNi, CoNiFeB, FeNi, FeCo, and CoNiPt.

In the case of producing the chemical sensor, from the viewpoints of sensitivity and chemical stability, noble metal may preferably be used as the substrate material.

In the case of producing the quantum dot laser device, e.g., semiconductor materials such as fine particles of Si, SiGe, GaAs, InGaAs, GaN, InP, InAs, AlGaAs, InGaAsP, GaInAlP, InGaN, and AlGaN may be used as the substrate material.

The processing of the substrate can be performed by dry etching using reactive plasma or radical, ion milling, or wet etching. The dry etching using reactive plasma is particularly preferred since it is suitable for pattern formation with high definition and high perpendicularity.

Dry etching as can be selected depending on an objective substrate, e.g., from CF₄, C₂F₆, C₃F₈, CCl₂F₂, CCl₄, CBrF₃, BCl₃, PCl₃ SF₆, CL₂ HCl, HBr, O₂, N₂, Ar, and the like, in the form of plasma.

An agent for the wet etching may be selected depending on an etching object from aqueous solutions of hydrofluoric acid, ammonium fluoride, phosphoric acid, acetic acid, nitric acid, ceric ammonium nitrate, potassium hydroxide, tetramethylammonium hydroxide, etc.

Further, it is also possible to form a hole array pattern of a desired material by forming a layer 120 of a material constituting a device on an entire surface of the above prepared substrate having the pattern of fine particles 105 and subjecting the pattern-formed substrate to lift-off process (FIG. 4). In FIG. 4, the silane coupling agent layer 101 formed on the substrate 100 is omitted.

The device material layer 120 can be formed by various coating methods such as physical vapor deposition (PVD), chemical vapor deposition (CVD), dipping, and spin coating.

Examples of the PVD may include various vacuum deposition methods such as electron beam heating, resistance heating, flash deposition, and the like; various sputtering methods such as plasma deposition, diode sputtering, DC sputtering, DC magnetron sputtering, high frequency sputtering, magnetron sputtering, ion beam sputtering, bias sputtering, and the like; and various ion plating methods such as DC method, RF method, multi-cathode method, activation reaction method, electrolytic deposition, high frequency ion plating, reactive ion plating, and the like.

After the film (layer) formation, the substrate is dipped into an organic solvent, an aqueous alkali solution, or an aqueous acidic solution to remove the fine particles and the film adhered onto the fine particles.

It is desirable that heating, oscillation, or the like is performed as desired.

By using the above formed fine particle pattern, hole array pattern, or dot array pattern, it is possible to produce the single electronic device, the patterned media, or the chemical sensor. Further, it is also possible to produce the quantum dot laser device having a quantum dot array structure or the photonic crystal optical device having a two-dimensional photonic crystal structure. It is also possible to form a tunnel junction site by using the pattern forming method of the present invention.

The above described pattern forming method of this embodiment is capable of performing a method (using the negative resist or the non-chemically amplified positive resist as the resist) in which no acid is generated at the fine particles adhered portion.

By the pattern forming method of this embodiment, it is also possible to ensure reactivity of the fine particles adhered portion even after the resist patterning.

Further, uniformity of a degree of adherence at each fine particles adhered site can be improved, so that it is possible to improve throughput of the entire device production.

The present invention will be described more specifically based on a specific embodiment but is not limited thereto.

### Embodiment 1

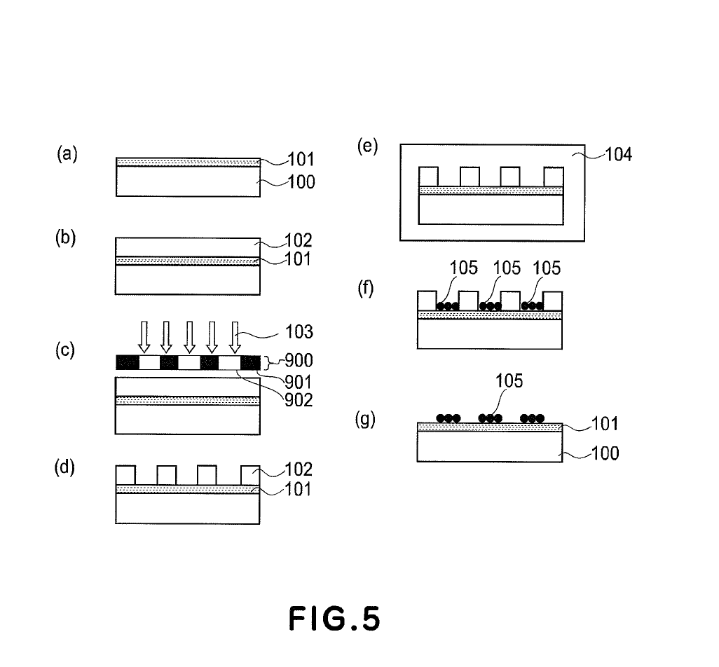

Embodiment 1 will be described with reference to FIGS. 5(a) to 5(g).

As a substrate 100, an Si substrate is used. The Si substrate is subjected to surface treatment with hydrogen peroxide and thereafter 3-aminopropyl-triethoxysilane is applied onto the substrate, followed by baking in an oven at 120° C. for 30 minutes to form a (monomolecular layer of) silane coupling agent layer 101 (FIG. 5(a)).

Next, a non-chemically amplified positive resist (“Az 7904”, mfd. by Clariant (Japan) K.K.) is applied onto the silane coupling agent layer 101 by using a spin coater and baked on a hot plate at 90° C. for 90 seconds to form a resist layer 102 (FIG. 5(b)).

BY using an exposure apparatus (not shown) capable of bringing an exposure mask 900 into close proximity to the resist layer 102 by pressing the entire exposure mask 900, the exposure mask 900 is brought into close proximity to the resist layer 102. The exposure mask 900 is partially provided with a pattern such that a light-blocking portion 901 and a mask opening 902 provide a line-and-space pattern with a pitch of 120 nm. As radiation light 103, light is emitted for 30 seconds from a mercury lamp to form a latent image (not shown) in the resist layer 102 below the mask opening 902 (FIG. 5(c)).

The substrate provided with the resist is dipped into a developing liquid (“MIF600”, mfd. by Clariant (Japan) K.K.) for 10 seconds and thereafter is rinsed with pure water for 20 seconds to form a resist pattern with a pitch of 120 nm (FIG. 5(d)).

The thus treated substrate is dipped into a colloid solution of gold fine particles having a particle size of 20 nm (mfd. by Funakoshi Corporation) for 1 hour (FIG. 5(e)) and then washed with pure water. As a result, at a portion where the silane coupling agent layer 101 is not covered with the resist layer 102, god fine particles 105 are adhered (FIG. 5(f)).

By removing the resist layer 102, on the silane coupling agent layer 101 formed on the substrate 100, it is possible to form a pattern of the fine particles 105 with a pitch of 120 nm (FIG. 5(g)).

Any fine particle pattern can be formed by preparing a desired resist pattern.

In this embodiment, by using the dissolution inhibition positive resist, the amino group of the silane coupling agent layer at the fine particles adhered site is not damaged by the influence of the acid, so that reactivity with the fine particles can be ensured after the formation of the resist pattern. It is possible to improve uniformity in degree of each fine particles adherence, so that throughput of the entire device production can be improved.

While the invention has been described with reference to the structures disclosed herein, it is not confined to the details set forth and this application is intended to cover such modifications or changes as may come within the purpose of the improvements or the scope of the following claims.

This application claims priority from Japanese Patent Application No. 276062/2006 filed Oct. 10, 2006, which is hereby incorporated by reference.

What is claimed is:

1. A pattern forming method for forming a pattern comprising a plurality of fine particles disposed on a substrate, said method comprising:
a step of forming, on the substrate, a silane coupling agent-containing layer containing an amino group-containing silane coupling agent;
a step of forming a negative resist layer on the silane coupling agent-containing layer;
a step of selectively removing the negative resist layer to expose the silane coupling agent-containing layer; and
a step of disposing the plurality of fine particles on the exposed silane coupling agent-containing layer.

2. A method according to claim 1, wherein the negative resist is a chemically amplified resist.

3. A method according to claim 1, wherein the negative resist is a dissolution inhibition negative resist.

4. A method according to claim 1, wherein the fine particles have an average particle size in a range of 0.5 nm or more and 500 nm or less.

5. A method according to claim 1, wherein the fine particles are charged positively or negatively.

6. A method according to claim 1, wherein the fine particles have a terminal carboxyl group.

7. A method according to claim 1, wherein the fine particles have a terminal carboxylic anhydride group.

8. A method according to claim 1, wherein when the resist layer is selectively removed, exposure to near-field light generated from an exposure mask including a light blocking layer having an opening smaller than a wavelength of light from an exposure light source is effected.

9. A pattern forming method for forming a pattern comprising a plurality of fine particles selectively disposed on a substrate, said method comprising:
a step of forming, on the substrate, a silane coupling agent-containing layer containing an amino group-containing silane coupling agent;
a step of forming a dissolution inhibition positive resist layer on the silane coupling agent-containing layer;
a step of selectively removing the positive resist layer to expose the silane coupling agent-containing layer; and
a step of disposing the plurality of fine particles on the exposed silane coupling agent-containing layer.

10. A method according to claim 9, wherein the fine particles have an average particle size in a range of 0.5 nm or more and 500 nm or less.

11. A method according to claim 9, wherein the fine particles are charged positively or negatively.

12. A method according to claim 9, wherein the fine particles have a terminal carboxyl group.

13. A method according to claim 9, wherein the fine particles have a terminal carboxylic anhydride group.

14. A method according to claim 9, wherein when the resist layer is selectively removed, exposure to near-field light generated from an exposure mask including a light blocking layer having an opening smaller than a wavelength of light from an exposure light source is effected.

15. A process for producing a device, comprising:
producing a device by using a pattern forming method according to claim 1 or 9.

16. A process according to claim 15, wherein a tunnel junction site is formed by using a pattern forming method according to claim 1 or 9.

17. A process according to claim 15, wherein a magnetic bit array is formed by using a pattern forming method according to claim 1 or 9.

18. A process according to claim 15, wherein a quantum dot array structure is formed by using a pattern forming method according to claim 1 or 9.

19. A process according to claim 15, wherein a photonic crystal structure is formed by using a pattern forming method according to claim 1 or 9.
